(19) United States
(12) Patent Application Publication
(10) Pub. No.: US 2026/0282528 A1
(43) Pub. Date: Sep. 17, 2026

(54) GATE STRUCTURES

(71) Applicant: Taiwan Semiconductor Manufacturing Company, Ltd., Hsin-Chu (TW)

(72) Inventors: Chih-Wei Lee, New Taipei City (TW); Hsin-Han Tsai, Hsinchu (TW); Yi-Lun Li, Hsinchu (TW); Yu Tai Tsai, Yangmei City (TW)

(21) Appl. No.: 19/266,964

(22) Filed: Jul. 11, 2025

Related U.S. Application Data
(60) Provisional application No. 63/772,152, filed on Mar. 14, 2025.

(51) Int. Cl. H10D 84/83; H10D 30/00; H10D 30/01; H10D 62/10; H10D 64/66; H10D 84/01; H10D 84/85

(52) U.S. Cl. CPC H10D 84/83135; H10D 30/0191; H10D 64/669; H10D 84/014; H10D 84/0142; H10D 84/0177; H10D 84/0179; H10D 84/832; H10D 84/851; H10D 84/856; H10D 30/502; H10D 62/121

(57) ABSTRACT

An exemplary method includes forming a channel region comprising a plurality of nanostructures over a substrate, forming an isolation feature over the substrate and adjacent to a sidewall of the channel region, forming a gate structure over the channel region and interfacing a top surface of the isolation feature. The forming of the gate structure comprises depositing a gate dielectric layer over the plurality of nanostructures and the isolation feature, depositing a p-type work function metal layer over the gate dielectric layer, partially removing a portion of the gate dielectric layer and p-type work function metal layer over the isolation feature, after the partially removing, soaking the p-type work function metal layer using a silicon-containing gas, depositing an n-type work function metal layer having a non-uniform thickness, and depositing a conductive layer over the n-type work function metal layer.

### PRIORITY DATA

This application claims priority to U.S. Provisional Patent Application No. 63/772,152, filed on Mar. 14, 2025, which is hereby incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors (both also referred to as non-planar transistors) are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). Compared to planar transistors, such configuration provides better control of the channel and drastically reduces SCEs (in particular, by reducing sub-threshold leakage (i.e., coupling between a source and a drain of the FinFET in the “off” state)). A GAA transistor has a gate structure that can extend, partially or fully, around a channel region to provide access to the channel region on two or more sides. The channel region of the GAA transistor may be formed from nanowires, nanosheets, other nanostructures, and/or other suitable structures. These shapes of the channel region also give a GAA transistor different names. For example, a GAA transistor with nanosheet channel regions may be referred to as a nanosheet transistor. Formation of GAA transistors brings challenges.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 is a flowchart illustrating a method of forming a semiconductor device according to various aspects of the present disclosure.

FIGS. 2, 3, 4, 5A, 5B, 6A, 6B, 7A, 7B, 8A, 8B, 9A, 9B, 9C, 10, 11, 12, 13, 14, 15, 16, 17, 18A, 18B illustrate fragmentary cross-sectional views of a first area and a second area of a precursor structure at various stages of fabrication in accordance with the method in FIG. 1.

FIGS. 19 and 20 illustrate alternative semiconductive devices fabricated in accordance with the method in FIG. 1, according to various aspects of the present disclosure.

FIGS. 21, 22, and 23 illustrate various diagrams showing simulation results related to the semiconductor device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

A GAA transistor has a gate structure that extends, partially or fully, around a channel region to provide access to the channel region on two or more sides. A channel region of a GAA transistor may include multiple sheet-like or wire-like nano-size channel members that are stacked one over another or placed side by side. Formation of GAA transistors comes with its own challenges. For example, without silicon germanium channels to help lower threshold voltage for p-type GAA transistors, work function metal layers having work functions closer to the valence band are needed to keep a low threshold voltage. Diffusion of impurities from an n-type work function metal layer into the p-type work function metal layer may impact performance of the p-type GAA transistor.

The present disclosure relates to formation of gate structures for p-type GAA transistors and n-type GAA transistors on a substrate. A precursor structure that includes nanostructures in a first region and nanostructures in a second region is received. After forming an interfacial layer and a gate dielectric layer over the nanostructures, a first work function metal (WFM) layer is deposited over the nanostructures in the first region and the second region. After the deposition of the first WFM layer, a barrier layer is deposited over the first WFM layer. Portions of the barrier layer and the first WFM layer over the first region are then selectively removed to expose the gate dielectric layer thereunder, while portions of the barrier layer and the first WFM layer over the second region remains. After the selective removal, a second WFM layer is deposited over the first region and the second region. The presence of the barrier layer reduces a deposition rate of forming the second WFM layer thereon. Thus, a second portion of the second WFM layer on the barrier layer has a smaller thickness than a first portion of the second WFM on the gate dielectric layer. In some examples, the barrier layer includes silicon. Forming a thinned second WFM layer over the second region may lead to a reduced amount of aluminum elements over the first WFM layer and thus reduces aluminum diffusion.

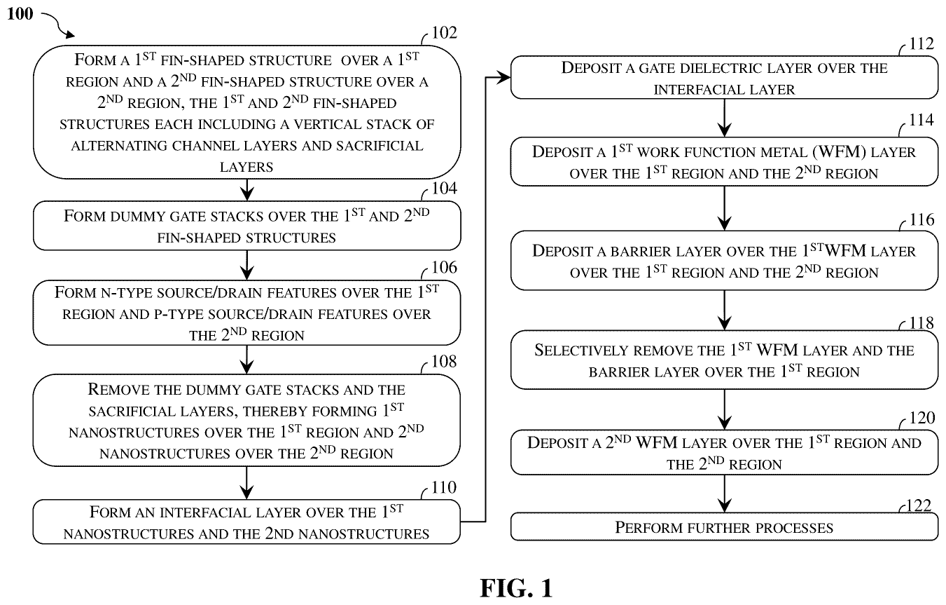

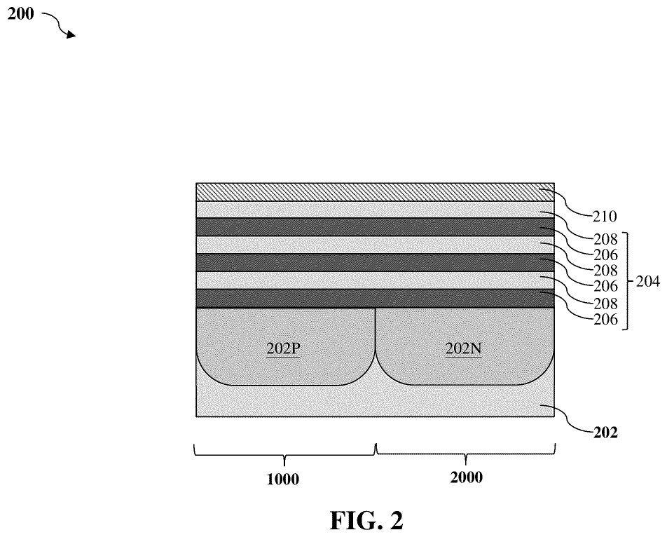

The various aspects of the present disclosure will now be described in more detail with reference to the figures. In that regard, FIG. 1 is a flowchart illustrating method 100 for forming multi-gate devices according to various aspects of the present disclosure. Method 100 is merely an example and is not intended to limit the present disclosure to what is explicitly illustrated in method 100. Additional steps may be provided before, during and after method 100 and some steps described can be replaced, eliminated, or moved around for additional embodiments of the method. Not all steps are described herein in detail for reasons of simplicity. Method 100 is described below in conjunction with FIGS. 2-20, which are fragmentary cross-sectional views of a precursor structure 200 at different stages of fabrication according to embodiments of method 100. Because the precursor structure 200 will be fabricated into a semiconductor device 200 upon conclusion of the fabrication processes, the precursor structure 200 may be referred to as the semiconductor device 200 as the context requires. Additionally, throughout the present application and across different embodiments, like reference numerals denote like features with similar structures and compositions, unless otherwise excepted. Source/drain region(s) may refer to a source or a drain, individually or collectively dependent upon the context.

Referring to FIGS. 1, 2, and 3, method 100 includes a block 102 where a fin-shaped structure 212a is formed over a first region 1000 of a substrate 202 and a fin-shaped structure 212b is formed over a second region 2000 of the substrate 202. In embodiment represented by FIG. 2, the substrate 202 is part of a precursor structure 200 that undergoes the various operations of method 100. In some embodiments, the substrate 202 may be a semiconductor substrate such as a silicon (Si) substrate. The substrate 202 may also include other semiconductors such as germanium (Ge), silicon carbide (SiC), silicon germanium (SiGe), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features. The substrate 202 may include various doping configurations depending on design requirements as is known in the art. In the depicted embodiments, the substrate 202 includes a first region 1000 and a second region 2000. The substrate 202 includes a p-type well 202P (i.e., a p-type dopant profile) over the first region 1000 and an n-type well 202N (i.e., an n-type doping profile) over the second region 2000. In some implementations, the n-type dopant for forming the n-type well 202N may include phosphorus (P) or arsenic (As) and the p-type dopant for forming the p-type well 202P may include boron (B). The suitable doping for the n-type well 202N or the p-type well 202P may include ion implantation of dopants and/or diffusion processes. As will be described later, an n-type GAA transistor will be formed over the first region 1000 and a p-type transistor will be formed over the second region 2000.

Still referring to FIG. 2, a stack 204 is formed over the substrate 202. The stack 204 includes sacrificial layers 206 of a first semiconductor composition interleaved by channel layers 208 of a second semiconductor composition. The first and second semiconductor compositions may be different. In some embodiments, the sacrificial layers 206 include silicon germanium (SiGe) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 2 and 10.

In some embodiments, all sacrificial layers 206 may have a substantially uniform first thickness between about 5 nm and about 20 nm and all of the channel layers 208 may have a substantially uniform second thickness between about 2 nm and about 8 nm. The first thickness and the second thickness may be identical or different. As described in more detail below, the channel layers 208 or parts thereof may serve as channel member(s) for a subsequently-formed multi-gate device and the thickness of each of the channel layers 208 is chosen based on device performance considerations. The sacrificial layers 206 in channel regions(s) may eventually be removed and serve to define a vertical distance between adjacent channel region(s) for a subsequently-formed multi-gate device and the thickness of each of the sacrificial layers 206 is chosen based on device performance considerations. The layers in the stack 204 may be deposited using a molecular beam epitaxy (MBE) process, a vapor phase deposition (VPE) process, and/or other suitable epitaxial growth processes at a temperature between about 600° C. and about 800° C. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 cm⁻³ to about 1×10¹⁷ cm⁻³), where for example, no intentional doping is performed during the epitaxial growth processes for the stack 204.

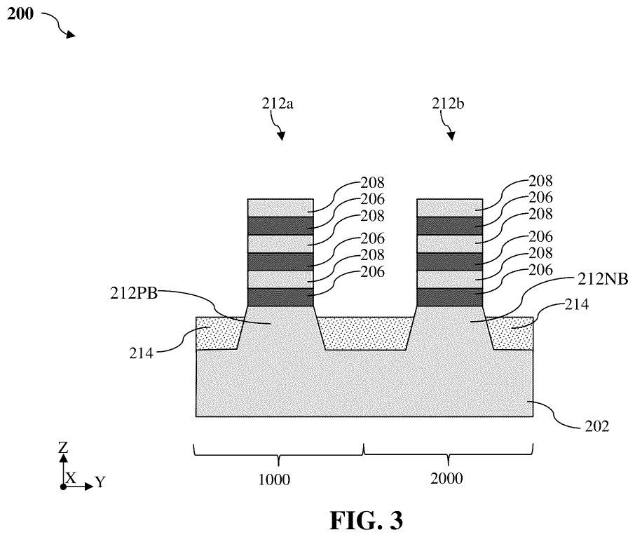

With reference to FIG. 3, fin-shaped structures 212a and 212b are formed from the stack 204 and a portion of the substrate 202. To pattern the stack 204, a hard mask layer 210 (shown in FIG. 2) may be deposited over the stack 204 to form an etch mask. The hard mask layer 210 may be a single layer or a multi-layer. For example, the hard mask layer 210 may include a pad oxide layer and a pad nitride layer over the pad oxide layer. The fin-shaped structures 212a and 212b may be patterned from the stack 204 and a portion of the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process forms trenches extending through the stack 204 and a portion of the substrate 202. The trenches define the fin-shaped structures 212a-212b, including base fins (e.g., a first base fin 212PB and a second base fin 212NB are shown in FIG. 3) formed from the substrate 202. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to form the fin-shaped structures 212a and 212b by etching the stack 204 and a portion of the substrate 202. The hard mask layer 210 may be selectively removed after the forming of the fin-shaped structures 212a and 212b. As shown in FIG. 3, the fin-shaped structures 212a-212b extend vertically along the Z direction and lengthwise along the X direction.

After forming the fin-shaped structures 212a-212b, an isolation feature 214 is formed adjacent the fin-shaped structures 212a-212b. In some embodiments, the isolation feature 214 may be formed in the trenches to isolate one fin-shaped structure (e.g., fin-shaped structure 212a or fin-shaped structure 212b) from a neighboring active region, which may be another fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214. As shown in FIG. 3, while the base fins (including the first base fin 212PB and the second base fin 212NB) are partially disposed in or surrounded by the STI feature 214, the rest of the fin-shaped structures 212a and 212b that are formed from the stack 204 rise above the STI feature 214 after the recessing.

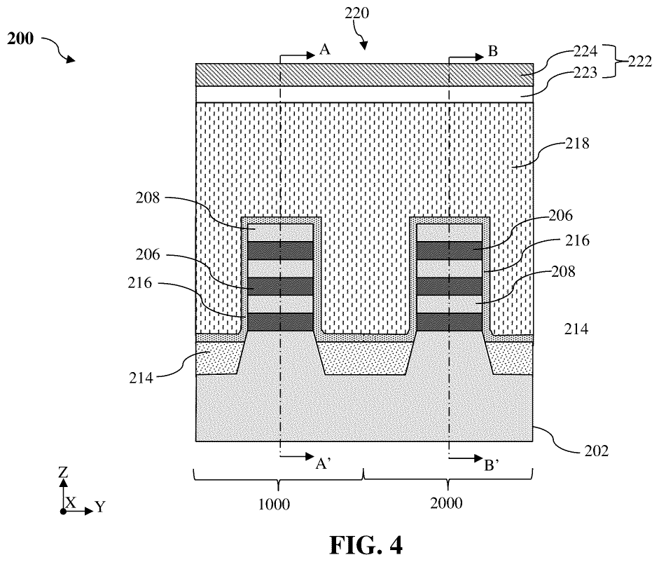

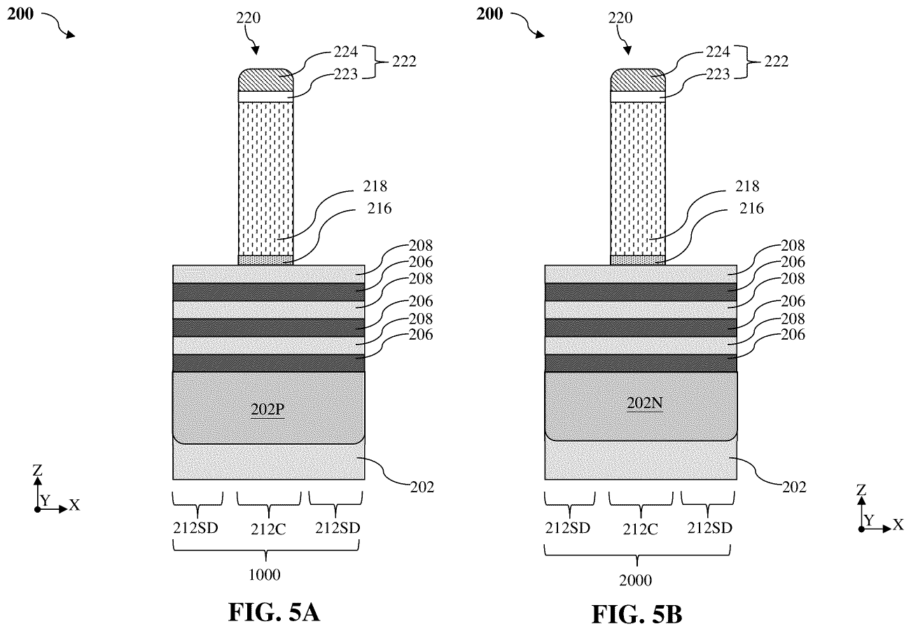

Referring to FIGS. 1 and 4, 5A-5B, method 100 includes a block 104 where dummy gate stack(s) 220 is formed over the fin-shaped structure 210a and the fin-shaped structure 210b. FIG. 5A depicts a fragmentary cross-sectional view of the precursor structure 200 taken along line A-A′ shown in FIG. 4, and FIG. 5B depicts a fragmentary cross-sectional view of the precursor structure 200 taken along line B-B′ shown in FIG. 4. A dummy gate stack 220 is formed over a channel region 212C of the fin-shaped structure 212a/212b. In some embodiments, a gate replacement process (or gate-last process) is adopted where the dummy gate stack 220 serves as a placeholder to undergo various processes and is to be removed and replaced by the functional gate structure. Other processes and configuration are possible. In some embodiments illustrated in FIG. 5A-5B, dummy gate stacks 220 are formed over the fin-shaped structures 212a and 212b, and the fin-shaped structures 212a and 212b may be each divided into channel regions 212C underlying the dummy gate stacks 220 and source/drain regions 212SD that do not underlie the dummy gate stacks 220. The channel regions 212C are adjacent to the source/drain regions 212SD. The channel region 212C is disposed between two source/drain regions 212SD along the X direction.

The formation of the dummy gate stack 220 may include deposition of layers and patterning of these layers. Referring to FIG. 4, a dummy dielectric layer 216, a dummy electrode layer 218, and a gate-top hard mask layer 222 may be deposited over the precursor structure 200. In some embodiments, the dummy dielectric layer 216 may be formed on the fin-shaped structures 212a and 212b using a chemical vapor deposition (CVD) process, an atomic layer deposition (ALD) process, an oxygen plasma oxidation process, a thermal oxidation process, or other suitable processes. In some instances, the dummy dielectric layer 216 may include silicon oxide. When the dummy dielectric layer 216 is formed using an oxidation process, it may be selectively formed on exposed surfaces of the fin-shaped structure 212, as illustrated in FIG. 4. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, a gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIGS. 5A-5B. For example, the patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIGS. 5A-5B, the dummy gate stack 220 is not disposed over the source/drain region 212SD of the fin-shaped structures 212a-212b.

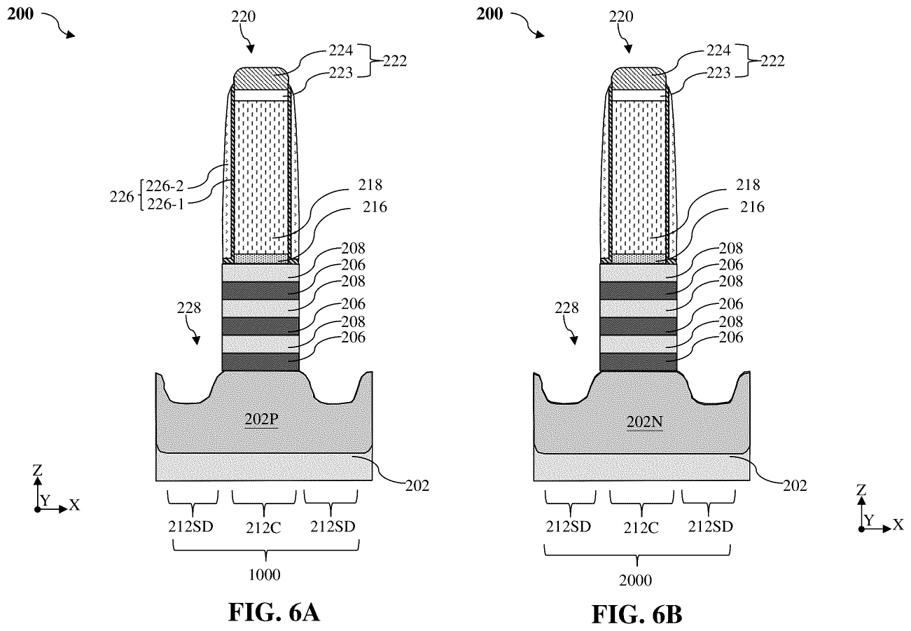

Referring to FIGS. 1 and 6A-6B, 7A-7B, method 100 includes a block 106 where n-type source/drain features 232N are formed over the first region 1000 and p-type source/drain features 232P are formed over the second region 2000. With reference to FIGS. 6A-6B, after forming the dummy gate stack(s) 220, at least one gate spacer layer 226 is deposited over the dummy gate stack(s) 220 over the first region 1000 and the second region 2000. In some embodiments, the at least one gate spacer layer 226 is deposited conformally over the precursor structure 200, including over top surfaces and sidewalls of the dummy gate stack 220. The term “conformally” may be used herein for ease of description of a layer having substantially uniform thickness over various regions. The at least one gate spacer layer 226 may be a single layer or a multi-layer. In the depicted embodiments, the at least one gate spacer layer 226 includes a first spacer layer 226-1 and a second spacer layer 226-2 disposed over the first spacer layer 226-1. A composition of the first spacer layer 226-1 may be different from a composition of the second spacer layer 226-2. In some implementations, a dielectric constant of the first spacer layer 226-1 is greater than a dielectric constant of the second spacer layer 226-2. The at least one gate spacer layer 226, including the first spacer layer 226-1 and the second spacer layer 226-2, may include silicon oxide, silicon carbonitride, silicon oxycarbide, silicon oxycarbonitride, or silicon nitride. The at least one gate spacer layer 226 may be deposited over the dummy gate stack 220 using processes such as, a CVD process, a subatmospheric CVD (SACVD) process, an ALD process, or other suitable process. For ease of reference, the at least one gate spacer layer 226 may also be referred to as the gate spacer layer 226 for simplicity.

Source/drain regions 212SD of the fin-shaped structures 212a and 212b are recessed to form source/drain trenches 228 (shown in FIGS. 6A-6B). In some embodiments, the source/drain regions 212SD that are not covered by the dummy gate stack(s) 220 and the gate spacer layer 226 are etched by a dry etch or a suitable etching process to form the source/drain trenches 228. For example, the dry etch process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some embodiments represented in FIGS. 6A-6B, the source/drain regions 212SD of the fin-shaped structures 212a and 212b are recessed to expose sidewalls of the sacrificial layers 206 and the channel layers 208. In some implementations, the source/drain trenches 228 extend below the stack 204 into the substrate 202.

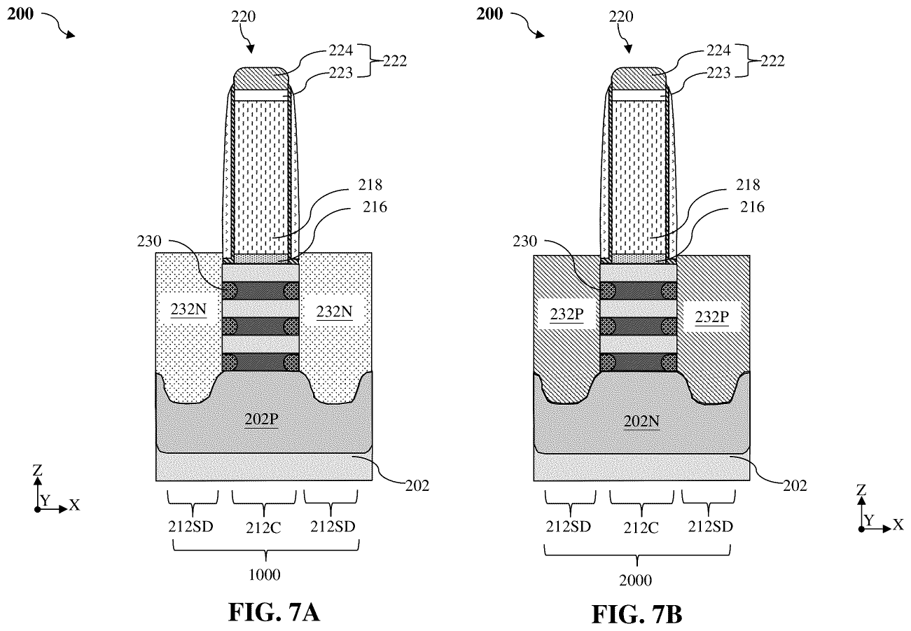

With reference to FIGS. 7A-7B, inner spacer features 230 are formed. After the formation of the source/drain trenches 228, the sacrificial layers 206 in the channel regions 212C are selectively and partially recessed to form inner spacer recesses, while the exposed channel layers 208 are substantially unetched. In an embodiment where the channel layers 208 consist essentially of silicon (Si) and sacrificial layers 206 consist essentially of silicon germanium (SiGe), the selective and partial recess of the sacrificial layers 206 may include a SiGe oxidation process followed by a SiGe oxide removal. In that embodiment, the SiGe oxidation process may include use of ozone (O₃). In some other embodiments, the selective recess may be a selective isotropic etching process (e.g., a selective dry etching process or a selective wet etching process), and the extent at which the sacrificial layers 206 are recessed is controlled by duration of the etching process. The selective dry etching process may include use of one or more fluorine-based etchants, such as fluorine gas or hydrofluorocarbons. The selective wet etching process may include an APM etch (e.g., ammonia hydroxide-hydrogen peroxide-water mixture). After the formation of the inner spacer recesses, an inner spacer material layer is deposited over the precursor structure 200, including in the inner spacer recesses. The inner spacer material layer may include silicon oxide, silicon nitride, silicon oxycarbide, silicon oxycarbonitride, silicon carbonitride, metal nitride, or a suitable dielectric material and may be deposited using CVD, PECVD, SACVD, ALD or other suitable methods. The deposited inner spacer material layer is then etched back to remove excess inner spacer material layer over the gate spacer layer 226 and sidewalls of the channel layers 208, thereby forming the inner spacer features 230. In some embodiments, the etch back process to form the inner spacer features 230 may be a dry etch process that includes use of an oxygen-containing gas, hydrogen (H₂), nitrogen (N₂), a fluorine-containing gas (e.g., NF₃, CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas (e.g., CF₃I), other suitable gases and/or plasmas, and/or combinations thereof. While not explicitly shown, a cleaning process may be performed after the etch back process to remove native oxide and debris from surfaces of the channel layers 208. Notably, the formation of the inner spacer features 230, including respective manufacturing steps described above, may be optional. That is, the formation of the inner spacer features 230 may be omitted, and the inner spacer features 230 may not exist in the final structure, in some embodiments.

Reference is still made to FIGS. 7A-7B. Source/drain features 232N are formed over source/drain regions 212SD over the first region 1000 and source/drain features 232P are formed over source/drain regions 212SD over the second region 2000. Each of the source/drain features 232N and the source/drain features 232P may be epitaxially and selectively formed from the exposed sidewalls of the channel layers 208 and exposed surfaces of the substrate 202, while sidewalls of the sacrificial layers 206 remain covered by the inner spacer features 230. Suitable epitaxial processes for formation of the source/drain features 232N and the source/drain features 232P include vapor-phase epitaxy (VPE), ultra-high vacuum CVD (UHV-CVD), molecular beam epitaxy (MBE), and/or other suitable processes. The epitaxial growth process may use gaseous precursors, which interact with the composition of the substrate 202 and the channel layers 208. In some embodiments, parameters of the epitaxial growth process are selected such that the source/drain features 232N and the source/drain features 232P are not epitaxially deposited on the inner spacer features 230. That said, the overgrowth of the source/drain features 232N and the source/drain features 232P may merge over some of the inner spacer feature 230.

The source/drain features 232N and the source/drain features 232P have different conductivity types and may each include more than one epitaxial layer. In some embodiments represented in FIG. 7, the source/drain features 232N over the first region 1000 may be n-type source/drain features that include silicon (Si) doped with an n-type dopant, such as phosphorus (P) or arsenic (As), and the source/drain features 232P over the second region 2000 may be p-type source/drain features that include silicon germanium (SiGe) doped with a p-type dopant, such as boron (B). When each of the source/drain features 232N includes multiple epitaxial layers, the epitaxial layer closer to the channel layers 208 and the substrate 202 may include lower n-type dopant concentrations and the epitaxial layer(s) away from the channel layers 208 and the substrate may include higher n-type dopant concentrations. Similarly, when each of the source/drain features 232P includes multiple epitaxial layers, the epitaxial layer closer to the channel layers 208 and the substrate 202 may include lower p-type dopant concentrations and the epitaxial layer(s) away from the channel layers 208 and the substrate may include higher p-type dopant concentrations. Because the source/drain features 232N and the source/drain features 232P have different compositions and are formed in different regions, they are formed separately and in a sequential order. In one embodiment, a patterned mask layer, such as a photoresist layer or a bottom antireflective coating (BARC) layer, may be formed to cover the second region 2000, while the source/drain features 232N are formed over the first region 1000. Then another patterned mask layer may be formed to cover the first region 1000, while the source/drain features 232P are formed over the second region 2000. In another embodiment, the order may be switched and the source/drain features 232P are first formed over the second region 2000. While not explicitly shown in the figures, an anneal process may be performed to obtain a desired electronic contribution of the dopant in the semiconductor host, such as silicon germanium (SiGe) or silicon (Si). The anneal process may include a rapid thermal anneal (RTA) process, a laser spike anneal process, a flash anneal process, or a furnace anneal process. The anneal process may include a peak anneal temperature between about 900° C. and about 1000° C. In these implementations, the peak anneal temperature may be maintained for a duration measured by seconds or microseconds.

In various embodiments, before forming the source/drain features 232N and the source/drain features 232P, an interposing layer (not shown) may be formed in lower portions of the source/drain trenches 228, and the source/drain features 232N and the source/drain features 232P will be later formed on the interposing layer and in upper portions of the source/drain trenches 228. In some embodiments, the interposing layer is a buffer epitaxial layer epitaxially grown from exposed top surfaces of the substrate 202. By way of example, epitaxial growth of the buffer epitaxial layer may be performed by VPE, ultra-high vacuum CVD (UHV-CVD), MBE, and/or other suitable epitaxial grow processes. In some embodiments, the interposing layer includes the same material as the substrate 202, such as silicon. In some alternative embodiments, the interposing layer includes a different semiconductor material other than silicon, such as SiGe, SiSn, or other suitable semiconductor material. The interposing layer may be dopant-free, where for example, no intentional doping is performed during the epitaxial growth process. As a comparison, in one instance, the substrate 202 is lightly doped and has a higher doping concentration than the buffer epitaxial layer. In embodiments in which the interposing layer includes a semiconductor material, a top surface of the interposing layer may be at a same level as or above a bottom surface of a bottommost sacrificial layer 206. In some other implementations, the interposing layer is a dielectric layer. In an exemplary process, a dielectric material layer (e.g., silicon nitride or other suitable materials) is formed over the substrate 202, including in the source/drain trenches 228, and then etched back to only keep portions of the dielectric material layer in a lower portion of the source/drain trenches 228 and on the exposed top surface of the substrate 202, thereby forming the dielectric layer as the interposing layer. A top surface of the dielectric layer may be above the bottom surface of the bottommost sacrificial layer and under a top surface of the bottommost sacrificial layer. In another implementation, the interposing layer may be a multi-layer structure that includes both the buffer epitaxial layer and the dielectric material layer. The dielectric material layer is formed on the buffer epitaxial layer. Notably, the formation of the interposing layer may be optional. That is, the formation of the interposing layer may be omitted, and the interposing layer may not exist in the final structure, in some embodiments.

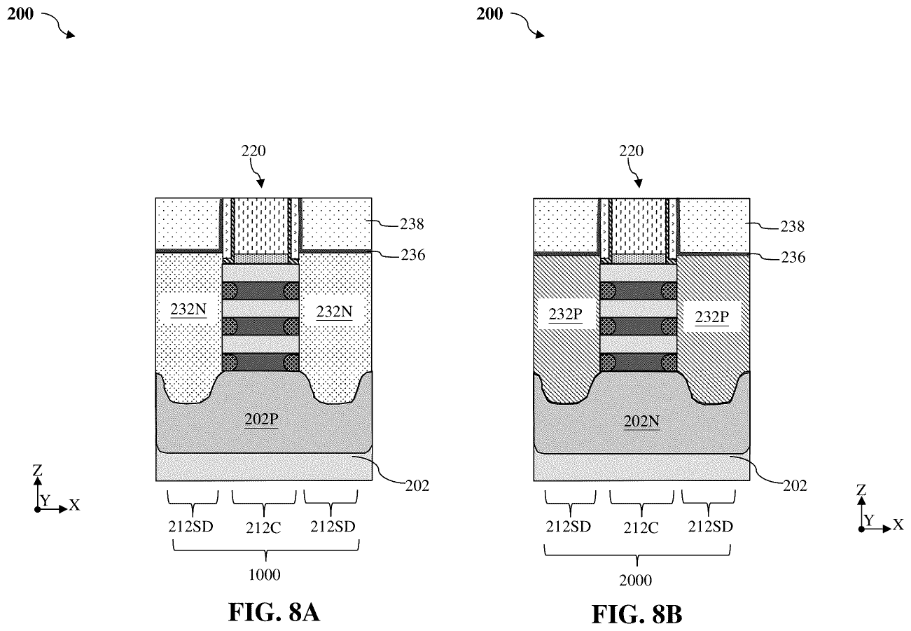

Referring to FIGS. 1, 8A-8B, and 9A-9C, method 100 includes a block 108 where the dummy gate stack(s) 220 and the sacrificial layers 206 are removed. With reference to FIGS. 8A-8B, a contact etch stop layer (CESL) 236 and an interlayer dielectric (ILD) layer 238 are deposited over the source/drain features 232N and the source/drain features 232P. The CESL 236 may include silicon nitride, silicon oxynitride, and/or other materials known in the art. The ILD layer 238 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the CESL 236 is first conformally deposited over the first region 1000 and the second region 2000 by CVD, ALD, plasma-enhanced chemical vapor deposition (PECVD) process and/or other suitable deposition or oxidation processes and the ILD layer 238 is deposited over the CESL 236 by spin-on coating, flowable CVD (FCVD), CVD, or other suitable deposition technique. In some embodiments, after formation of the ILD layer 238, the precursor structure 200 may be annealed to improve integrity of the ILD layer 238. As shown in FIGS. 8A-8B, after the deposition of the CESL 236 and the ILD layer 238, a planarization process, such as a chemical mechanical polishing (CMP) process, may be performed to remove excess materials. The planarization process also exposes the dummy electrode layers 218 over the first region 1000 and the second region 2000.

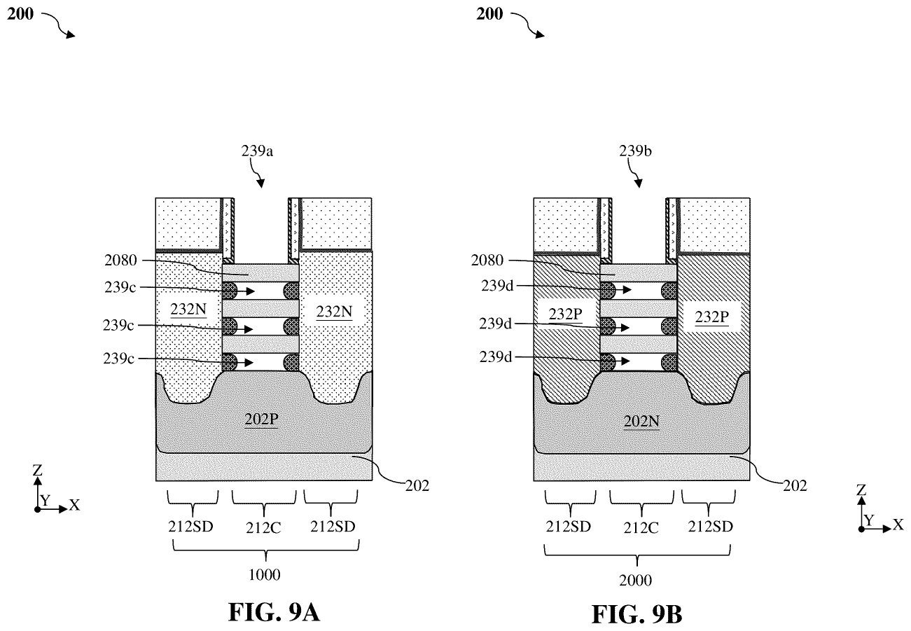

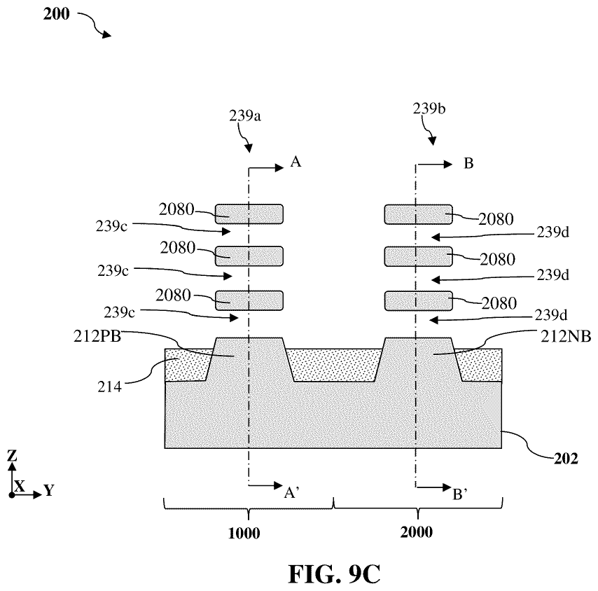

Reference is now made to FIGS. 9A-9C. FIG. 9A depicts a fragmentary cross-sectional view of the precursor structure 200 taken along line A-A′ shown in FIG. 9C, and FIG. 9B depicts a fragmentary cross-sectional view of the precursor structure 200 taken along line B-B′ shown in FIG. 9C. The exposed dummy gate stacks 220 are removed. The removal of the dummy gate stacks 220 may include one or more etching processes that are selective to the material in the dummy gate stacks 220. For example, the removal of the dummy gate stacks 220 may be performed using as a selective wet etch, a selective dry etch, or a combination thereof. After the removal of the dummy gate stacks 220, sidewalls of the channel layers 208 and sacrificial layers 206 in the channel regions 212C are exposed. The removal of the dummy gate stacks 220 forms gate trenches 239a over the first region 1000 and gate trenches 239b over the second region 2000. Then, the sacrificial layers 206 in the channel regions 212C are selectively removed to release the channel layers 208 as nanostructures 2080. The nanostructures 2080 may also be referred to as channel members. The selective removal of the sacrificial layers 206 may be implemented by selective dry etch, selective wet etch, or other selective etch processes. In some embodiments, the selective wet etching includes an APM etch (e.g., ammonia hydroxide-hydrogen peroxide-water mixture). In some other embodiments, the selective removal includes SiGe oxidation followed by a silicon germanium oxide removal. For example, the oxidation may be provided by ozone clean and then silicon germanium oxide removed by an etchant such as NH₄OH. The removal of the sacrificial layers 206 forms gate openings 239c over the first region 1000 and gate openings 239d over the second region 2000. Although not shown, in some embodiments, a sidewall surface of the topmost nanostructure 2080 of the nanostructures 2080 over the first region 1000 and a sidewall surface of the topmost nanostructure 2080 of the nanostructures 2080 over the second region 2000 may be tilted sidewall surfaces.

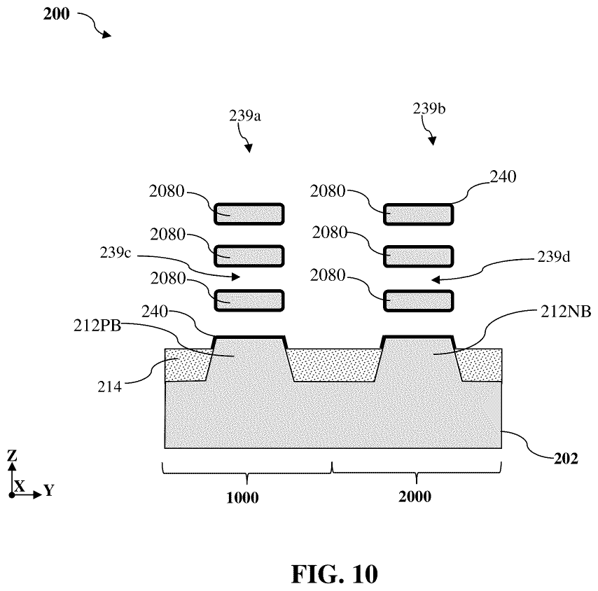

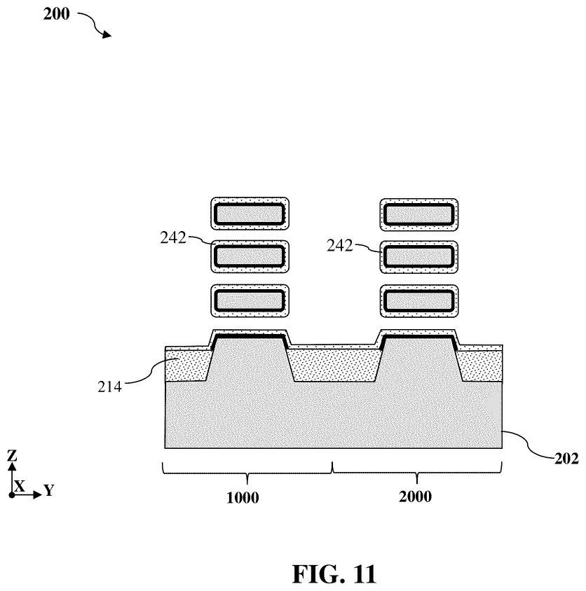

Referring to FIGS. 1 and 10, method 100 includes a block 110 where an interfacial layer 240 is formed over the nanostructures 2080 over the first region 1000 and the second region 2000. As shown in FIG. 10, the precursor structure 200 includes nanostructures 2080 disposed over the first base fin 212PB over the first region 1000 and nanostructures 2080 disposed over the second base fin 212NB over the second region 2000. Because the first base fin 212PB is patterned from the p-type well 202P, the first base fin 212PB includes the same composition with the p-type well 202P. Because the second base fin 212NB is patterned from the n-type well 202N, the second base fin 212NB includes the same composition with the n-type well 202N. In FIG. 10, the first region 1000 may be contiguous with the second region 2000. As a result, the p-type well 202P may interface the n-type well 202N. The interfacial layer 240 may include silicon oxide or silicon oxynitride, or other suitable material. In some embodiments, the interfacial layer 240 may be deposited over surfaces of the nanostructures 2080, top surfaces of the first base fin 212PB and the second base fin 212NB, and sidewalls of the portions of the first base fin 212PB and the second base fin 212NB above the isolation feature 214 using a suitable method, such as atomic layer deposition (ALD), chemical vapor deposition (CVD), ozone oxidation, thermal oxidation, or other suitable method. The interfacial layer 240 serves the function to control and reduce gate leakage current and improve interfacial adhesion between the gate dielectric layer 242 (shown in FIG. 11) and the nanostructures (including the nanostructures 2080 over the first region 1000 and the nanostructures 2080 over the second region 2000). In the depicted embodiments, the interfacial layer 240 is formed using thermal oxidation and the interfacial layer 240 is selectively deposited on semiconductor surfaces but not on dielectric surfaces, such as the top surfaces of the isolation feature 214.

Referring to FIGS. 1 and 11, method 100 includes a block 112 where a gate dielectric layer 242 is deposited over the interfacial layer 240. In some embodiments, the gate dielectric layer 242 is high-k dielectric layer as its dielectric constant is greater than that of silicon dioxide (~3.9). In some implementations, the gate dielectric layer 242 may include doped or undoped hafnium oxide (HfO₂), doped or undoped zirconium oxide (ZrO₂), doped or undoped titanium oxide (TiO₂), or doped or undoped aluminum oxide (Al₂O₃). For example, the gate dielectric layer 242 may include hafnium silicon oxide (HfSiO), hafnium silicon oxynitride (HfSiON), or hafnium aluminum oxide (HfAlO), hafnium tantalum oxide (HfTaO), Hafnium zirconium oxide (HfZrO), zirconium silicon oxide (ZrSiO₂), hafnium titanium oxide (HfTiO), or a combination thereof. Dielectric constant of the gate dielectric layer 242 is greater than dielectric constant of the isolation feature 214. In some embodiments, the dielectric constant of the gate dielectric layer 242 is greater than dielectric constant of the gate spacer layer 226. In some other embodiments, the dielectric constant of the gate dielectric layer 242 is greater than dielectric constant of the ILD layer 238. Upon conclusion of operations at block 112, each of the nanostructures 2080 over the first region 1000 and the nanostructures 2080 over the second region 2000 is wrapped around by the interfacial layer 240 and the gate dielectric layer 242. Furthermore, as illustrated in FIG. 11, the deposition of the gate dielectric layer 242 may not be selective and the gate dielectric layer 242 may be deposited over the isolation feature 214.

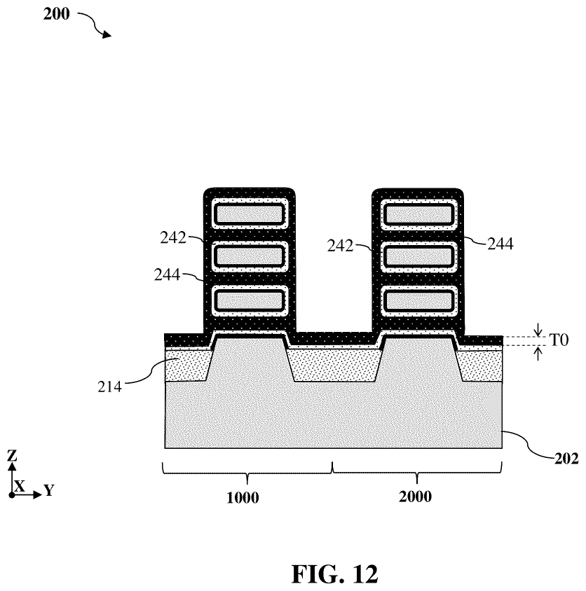

Referring to FIGS. 1 and 12, method 100 includes a block 114 where a first work function metal (WFM) layer 244 is deposited over the first region 1000 and the second region 2000. In some embodiments, the first WFM layer 244 may be a p-type WFM layer and may include titanium nitride (TiN), titanium silicon nitride (TiSiN), tantalum nitride (TaN), tungsten carbonitride (WCN), molybdenum (Mo), or other suitable p-type work function material. In one embodiment, the first WFM layer 244 includes titanium nitride (TiN). The first WFM layer 244 may be deposited using ALD at a temperature between about 300° C. and about 450° C. As shown in FIG. 12, a thickness T0 of the first WFM layer 244 is such that the gate openings 239c and 239d between two vertically adjacent nanostructures 2080 are fully filled after the deposition of the first WFM layer 244. In an embodiment, the thickness T0 is between about 10 Å and about 33 Å.

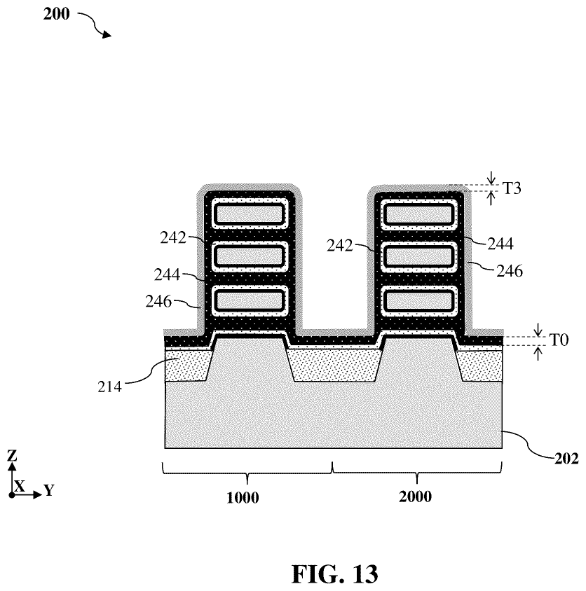

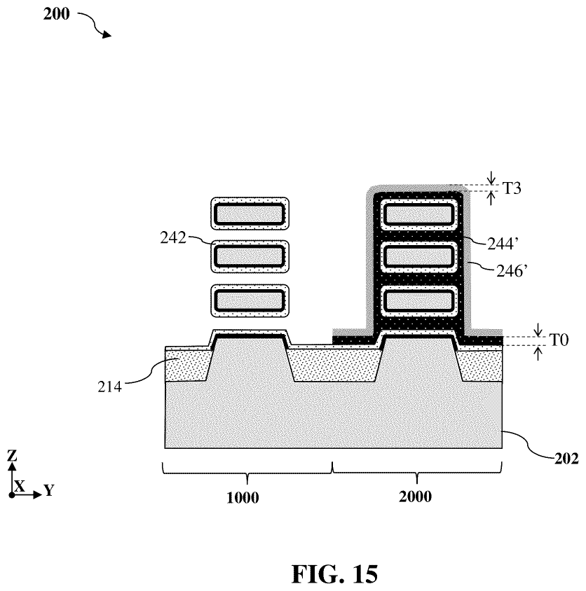

Referring to FIGS. 1 and 13, method 100 includes a block 116 where a barrier material 246 is deposited over the first WFM layer 244. In some exiting technologies, an n-type work function metal layer (e.g., the second WFM layer 250) may be deposited on a p-type work function metal layer (e.g., first WFM layer 244). However, elements (e.g., aluminum) of the n-type work function metal layer may diffuse into the p-type work function metal layer, disadvantageously affecting the threshold voltage Vt of the p-type transistors formed over the second region 2000. In this present disclosure, a barrier layer 246′ (shown in FIG. 15), formed by patterning the barrier material 246, will be formed on the p-type work function metal layer (e.g., the first WFM layer 244) over the second region 2000. Deposition rate for forming the n-type work function metal layer (e.g., the second WFM layer 250) on the barrier layer 246′ is less than deposition rate for forming the n-type work function metal layer (e.g., the second WFM layer 250) on the p-type function metal layer (e.g., first WFM layer 244) and on the gate dielectric layer 242. That is, due to the presence of the barrier layer 246′, the deposition rate for forming the second WFM layer 250 over the second region 2000 is reduced. In an embodiment, when a deposition process (e.g., ALD) is performed to form the second WFM layer 250, a deposition rate for forming the second WFM layer 250 on the barrier layer 246′ is less than a deposition rate for forming the second WFM layer 250 on the gate dielectric layer 242 and a deposition rate for forming the second WFM layer 250 directly on the first WFM layer 244. As a result, a thickness of the second WFM layer 250 on the barrier layer 246′ is less than a thickness of the second WFM layer 250 on the gate dielectric layer 242, while in some existing technologies, the second WFM layer 250 may have a uniform thickness over the first region 1000 and the second region 2000. Thus, compared to those existing technologies where there is no barrier material 246 disposed between the second WFM layer 250 and the first WFM layer 244 to affect the deposition rate for forming the second WFM layer 250, a total amount of aluminum over the second region 2000 of the present disclosure is reduced, leading to a reduced aluminum diffusion.

In some embodiments, the barrier material 246 includes silicon (silicon). For example, the barrier material 246 may be formed of silicon or a silicon-containing material such as silicon-containing titanium nitride. Materials of the barrier material 246 are selected such that the deposition rate described above will be reduced, and work function of the p-type gate structure and threshold voltage of the p-type transistor will not be adversely affected. According to embodiments of the present disclosure, the barrier material 246 may be deposited using atomic layer deposition (ALD) or a soak process. The soak process may use silane (SiH₄) or disilane (Si₂H₆). In an embodiment, the barrier material 246 may include amorphous silicon.

The barrier material 246 has a thickness T3. In an embodiment, a ratio of the thickness T0 to the thickness T3 may be in a range between about 2:1 and about 12:1. If the ratio is greater than 12:1, the thickness T3 and the amount of the silicon elements may be too small to affect the deposition rate described above; and if the ratio is less than about 2:1, the thickness T3 may be too large, and the difficulty of patterning the barrier material 246 and/or the patterning the first WFM layer 244 at block 118 may be increased. For example, a stronger etch process may be performed to remove portions of the barrier material 246 and the first WFM layer 244 over the first region 1000, and the stronger etch process may induce damage to neighboring features formed near the barrier material 246 and the first WFM layer 244. In an embodiment, the thickness T3 of the barrier material 246 is between about 2 Å and 10 Å. If the thickness of the barrier material 246 is too small, then the amount of the silicon elements may be too small to achieve the barrier effect; and if the thickness of the barrier material 246 is too large, then the difficulty of patterning the barrier material 246 and/or the patterning the first WFM layer 244 at block 118 may be increased.

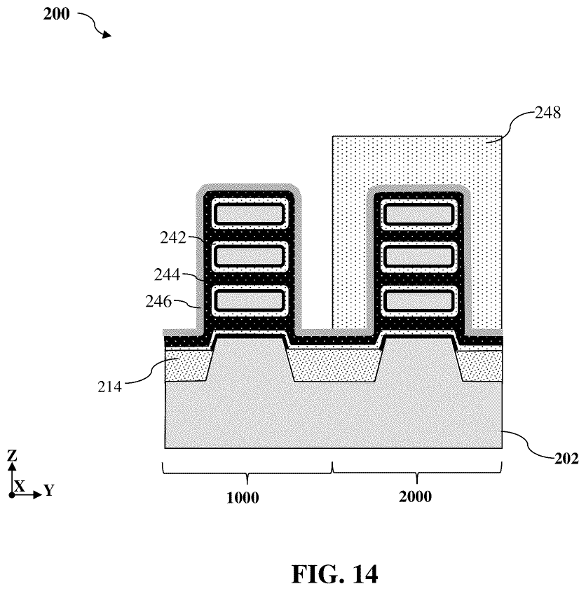

Referring to FIGS. 1, 14 and 15, method 100 includes a block 118 where portions of the first WFM layer 244 and the barrier material 246 over the first region 1000 are selectively removed. To selectively remove the barrier material 246 and the first WFM layer 244 over the first region 1000, a bottom antireflective coating (BARC) layer 248 is formed over the second region 2000 while the first region 1000 is exposed. In an example process, a blanket BARC layer is deposited over the first region 1000 and the second region 2000, and then a photoresist layer is deposited over the blanket BARC layer. The photoresist layer is pre-baked, patterned by exposure to a patterned radiation passing through or reflected from a mask, post-baked, and developed in a developing process using a developer, to form a patterned photoresist layer. The patterned photoresist layer is used as an etch mask to pattern the blanket BARC layer to form the BARC layer 248, as shown in FIG. 14. With the BARC layer 248 covering the second region 2000, the barrier layer 246′ and the first WFM layer 244 over the first region 1000 are removed. The removal of the barrier material 246 and the first WFM layer 244 may be performed using one or more etching process. After the barrier material 246 and the first WFM layer 244 are removed from the first region 1000, the BARC layer 248 may be removed from the second region 2000 using ashing or a selective etching process, as illustrated in FIG. 15. The first WFM layer 244 after the patterning may be referred to as the first WFM layer 244′. The barrier material 246 after the patterning may be referred to as the barrier layer 246′.

In the above embodiments, the formation of the first WFM layer 244′ and the barrier layer 246′ includes depositing the first WFM layer 244 and the barrier material 246 over both the first region 1000 and the second region 2000, then, forming a mask covering features over the second region 2000, and then patterning, thereby removing portions of the first WFM layer 244 and the barrier material 246 over the first region 1000. In some other implementations, the formation of the first WFM layer 244′ and the barrier layer 246′ may include forming a mask covering the first region 1000 while the second region 2000 is not covered, then, depositing the first WFM layer 244 and the barrier material 246 over both the first region 1000 and the second region 2000, removing (e.g., by performing a planarization process, by performing a lift-off process if the mask includes a photoresist) portions of the first WFM layer 244 and the barrier material 246 over the mask layer. In another implementation, the formation of the first WFM layer 244′ and the barrier layer 246′ may include, after forming the gate dielectric layer 242, forming a mask to fill remaining portions of the gate openings 239c, while gate openings 239d remain the same as represented by the figures, then, depositing the first WFM layer 244 and the barrier material 246 over both the first region 1000 and the second region 2000, removing (e.g., by performing a planarization process) portions of the first WFM layer 244 and the barrier material 246 over the mask layer, and then removing the mask.

As described above, the barrier material 246 (and thus the barrier layer 246′) has a thickness T1 between about 2 Å and about 10 Å. In some cases, the barrier layer 246′ may be detected using a transmission electron microscopy (TEM). In some other cases, the barrier layer 246′ may be identified by an energy-dispersive spectroscopy (EDS). When EDS is used for elemental analysis or chemical characterization, a high-energy beam of electrons strikes the semiconductor device 200 including the barrier layer 246′. This interaction excites atoms in the semiconductor device 200, causing the atoms in the semiconductor device 200 to emit X-rays. The energy of these emitted X-rays is characteristic of the elements present in the sample. An energy-dispersive detector measures the energy and intensity of the X-rays, producing a spectrum. In an embodiment, the nanostructures 2080 are formed of silicon, and the barrier layer 246′ includes silicon or is formed of silicon. As a reference, the intensity of the X-rays associated with the nanostructures 2080 may be regarded as 100%, and the intensity of the X-rays associated with the barrier layer 246′ may be between about 1% and about 15%.

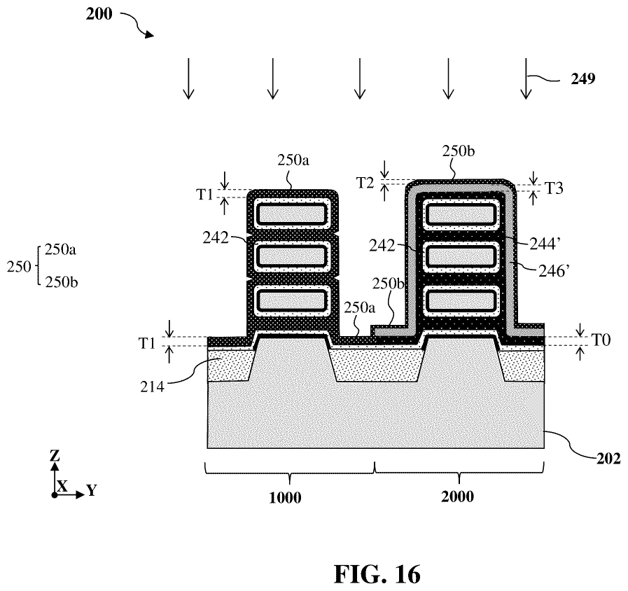

Referring to FIGS. 1 and 16, method 100 includes a block 120 where a second WFM layer 250 is deposited over the first region 1000 and the second region 2000. The second WFM layer 250 has a different conductivity type from the first WFM layer 244. In an embodiment, the second WFM layer 250 is an n-type WFM layer while the first WFM layer 244 is a p-type WFM layer. The second WFM layer 250 includes aluminum and may be referred to as an aluminum-containing layer. In some embodiments, the second WFM layer 250 may include titanium aluminum (TiAl), titanium aluminum carbide (TiAlC), tantalum aluminum (TaAl), tantalum aluminum carbide (TaAlC), titanium aluminum nitride (TiAlN), various combinations thereof. In one embodiment, the second WFM layer 250 includes titanium aluminum carbide (TiAlC). The second WFM layer 250 may be deposited using a deposition process 249 such as ALD. It is noted that, in various embodiments, aluminum may diffuse from the second WFM layer 250 into the barrier layer 246′. In some embodiments, aluminum may even diffuse into an upper portion of the first WFM layer 244′. However, compared to some existing technologies, the amount of diffused aluminum in the present disclosure is reduced.

As shown in FIG. 16, the second WFM layer 250 includes a portion 250a formed over the first region 1000 and a portion 250b formed over the second region 2000. In various embodiments, the portion 250b of the second WFM layer 250 refers to the portion of the second WFM layer 250 that is in physical contact with the barrier layer 246′, and the portion 250a of the second WFM layer 250 refers to the portion of the second WFM layer 250 that is not in physical contact with the barrier layer 246′. In this illustrated embodiment, the portion 250a of the second WFM layer 250 is formed on the gate dielectric layer 242 and has a generally uniform deposition thickness T1. The portion 250b of the second WFM layer 250 is formed on the barrier layer 246′ and has a generally uniform deposition thickness T2. As described above, due to the presence of the barrier layer′ 246 over the second region 2000, the portion 250b of the second WFM layer 250 is deposited on the barrier layer 246′ at a deposition rate less than the deposition rate of forming the portion 250a of the second WFM layer 250 on the gate dielectric layer 242. Thus, the thickness T2 is less than the thickness T1. By forming the thinner portion of the second WFM layer 250 over the second region 2000, the total amount of aluminum over the first WFM layer 244′ is reduced, and the extent of aluminum diffusion may be thus alleviated without changing the fabrication processes and threshold voltages of n-type transistor over the first region 1000. In an embodiment, a thickness difference between the thickness T1 and T2 is about 5 Å and about 15 Å. The thickness T1 may be between about 10 Å and about 33 Å, and the thickness T2 may be between about 5 Å and about 20 Å. In some embodiments, the thickness T1 is greater than a sum of the thickness T2 and the thickness T3. In various embodiments, a grain size of the second WFM layer 250 may be smaller than a grain size of the barrier layer 246′.

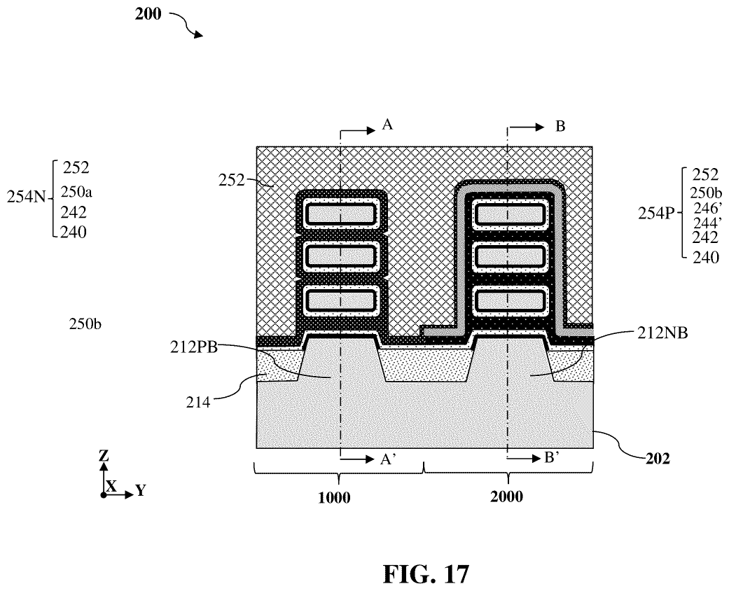

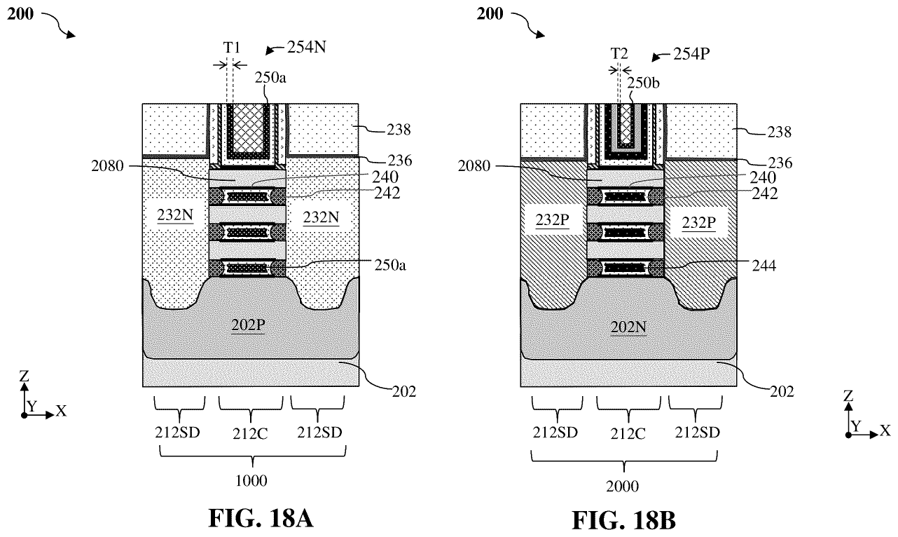

Referring to FIGS. 1 and 17, 18A-18B, method 100 includes a block 122 where further processes are performed to finish the fabrication of the semiconductor device 200. FIG. 18A depicts a fragmentary cross-sectional view of the precursor structure 200 taken along line A-A′ shown in FIG. 17, and FIG. 18B depicts a fragmentary cross-sectional view of the precursor structure 200 taken along line B-B′ shown in FIG. 17.

Such further processes may include forming a protective layer (not separately labeled) on the second WFM layer 250. The protective layer may be formed to prevent the second WFM layer 250 from being oxidized during subsequent processes. The protective layer may include a titanium-based material. In some embodiments, the protective layer may include titanium nitride (TiN) and is formed in-situ after the second WFM layer 250 is deposited. This prevents oxygen in the ambient air from coming in contact with the second WFM layer 250 when the vacuum is broken. In some embodiments, the protective layer may be formed by ALD. In some instances, at thickness of the protective layer is between about 8 Å and about 20 Å.

Such further processes may include, after forming the protective layer, forming a semiconductor cap layer (not separately labeled) over the protective layer. The semiconductor cap layer may include silicon (Si) and functions to prevent the protective layer from being oxidized during subsequent fabrication processes. In some embodiments, the semiconductor cap layer may be deposited using ALD and a silicon-containing precursor, such as silane (SiH₄) or disilane (Si₂H₆). In one embodiment, the semiconductor cap layer is deposited using disilane as a precursor. In some instances, the semiconductor cap layer may have a thickness between about 5 Å and about 15 Å. In some implementations, a precursor structure or a wafer having structures formed at blocks 102-120 is removed from a vacuum chamber after the deposition of the semiconductor cap layer. The exposure to ambient air may form a thin silicon oxide layer on the surface of the semiconductor cap layer. This thin silicon oxide layer may not be removed before deposition of further layers.

Such further processes may also include forming a metal fill layer over the semiconductor cap layer. In some embodiments, the metal fill layer may include tungsten (W) and may be deposited using ALD or CVD. In various embodiments, a glue layer may be formed between the metal fill layer and the semiconductor cap layer to increase the adhesion between the metal fill layer and the semiconductor cap layer. The glue layer may include titanium nitride. The various layers (e.g., the protective layer, the semiconductor cap layer, the glue layer, the metal fill layer) formed over the second work function metal layer 250 and in the gate trenches 239a and 239b may be collectively referred to as a gap filling layer 252. The formation of the gap filling layer 252 defines a gate structure 254N over the first region 1000 and a gate structure 254P over the second region 2000. The gate structure 254N includes the interfacial layer 240, the gate dielectric layer 242, the portion 250a of the second WFM layer 250, and the gap filling layer 252. The gate structure 254P includes the interfacial layer 240, the gate dielectric layer 242, the first WFM layer 244′, the barrier layer 246′, the portion 250b of the second WFM layer 250, and the gap filling layer 252. It is noted that the portion 250a of the second WFM layer 250 and the portion 250b of the second WFM layer 250 are formed during a common deposition process 249 and have different thicknesses. Compared with a reference p-type transistor that includes an n-type WFM layer having the thickness T1 over a p-type WFM layer, the p-type transistor of the present disclosure has a thinner n-type WFM layer (i.e., thickness T2). In some cases, a difference between a threshold voltage of the reference p-type transistor and a threshold voltage of the p-type transistor of the present disclosure is greater than about 20 mV.

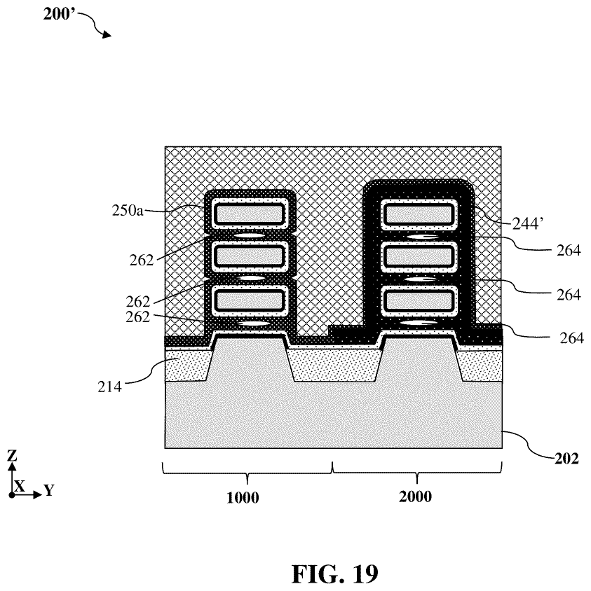

FIG. 19 illustrates an alternative semiconductor device 200′ formed using method 100. The semiconductor device 200′ in FIG. 19 is substantially similar to the semiconductor device 200 in FIG. 17, except that the second WFM layer 250 over the first region 1000 includes first seam(s) 262 and the first WFM layer 244′ over the second region 2000 includes second seam(s) 264. The first seams 262 and the second seams 264 are formed when the layer filling the space between two adjacent first nanostructures 2080 or two adjacent second nanostructures 2080 merge prematurely before it fills the space. The first seam(s) 262 may be positioned in the one or more of the gate openings 239c, and the second seam(s) 264 may be positioned in the one or more of the gate openings 239d.

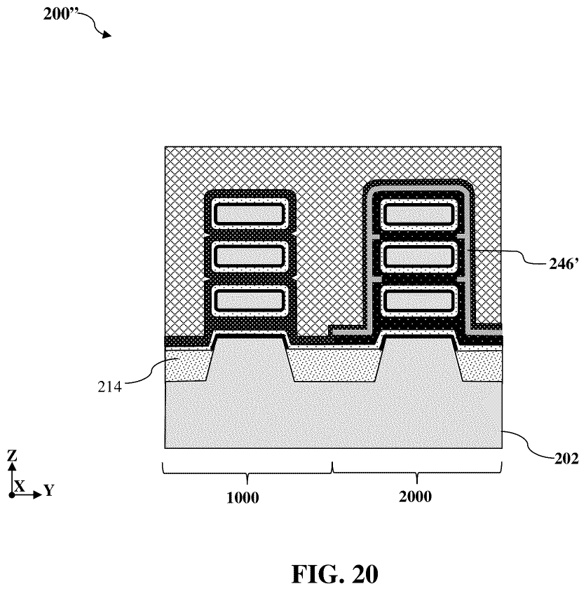

FIG. 20 illustrates another alternative semiconductor device 200″ formed using method 100. The semiconductor device 200″ in FIG. 20 is substantially similar to the semiconductor device 200 in FIG. 17, except that the barrier layer 246′ over the second region 2000 may fill spacings in and/or adjacent to the gate openings 239d not filled by the first WFM layer 244. For example, as illustrated by FIG. 20, a portion of the barrier layer 246′ may be disposed between two vertically adjacent nanostructures 2080 over the second region 2000. The width of this portion of the barrier layer 246′ may be dependent on the deposition thickness of the first WFM layer 244 and the dimensions of the gate openings 239d. For example, this portion of the barrier layer 246′ may or may not be vertically overlapped with the nanostructures 2080 over the second region 2000. In some embodiments, the semiconductor device 200″ may also include the first seam(s) 262 and/or the second seam(s) 264. The first seam(s) 262 may be physically separated from the barrier layer 246′ by the first WFM layer 244.

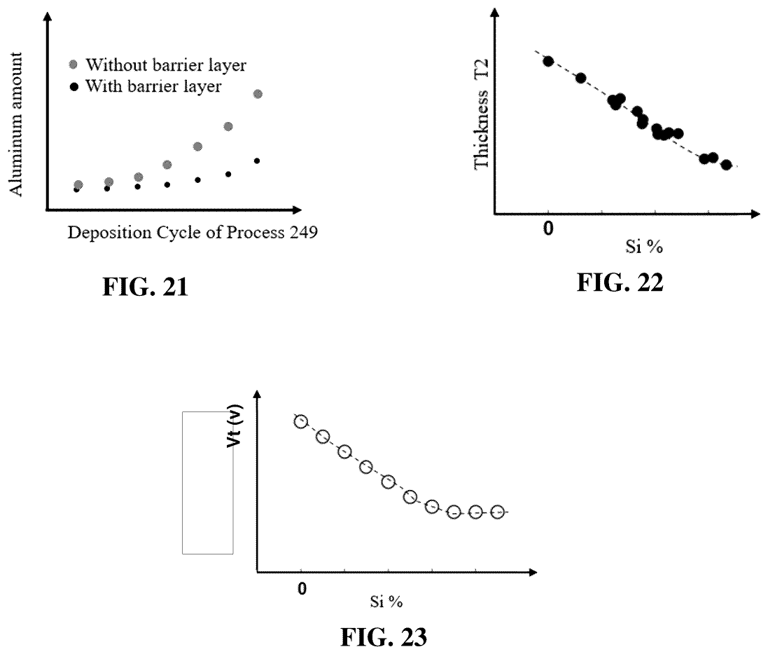

FIG. 21 depicts a diagram that illustrates a simulation result showing the relationship between the number of ALD cycles of the deposition process 249 (shown in FIG. 16) and the amount of aluminum of the second WFM layer 250. As illustrated by FIG. 21, the portion 250a of the second WFM layer 250 has a first amount (indicated by grey dots) of aluminum elements, and the portion 250b of the second WFM layer 250 has a second amount (indicated by black dots) of aluminum elements less than the first amount. And the greater the number of ALD cycles of the deposition process 249, the larger the difference between the first amount and the second amount.

FIG. 22 depicts a diagram that illustrates a simulation result showing the relationship between the intensity of the silicon elements in the barrier layer 246′ and the thickness T2 of the portion 250b of the second WFM layer 250 on the barrier layer 246′. As illustrated by FIG. 22, the higher the intensity of the silicon elements in the barrier layer 246′, the less the thickness T2. In this embodiment, the intensity of the silicon elements is related to a thickness T3 (shown in FIG. 13) of the barrier material 246. In this embodiment, the thickness T3 of the barrier material 246 is between about 2 Å and 10 Å. If the thickness of the barrier material 246 is too small, then the intensity of the silicon elements may be too small to achieve the barrier effect; and if the thickness of the barrier material 246 is too large, then the difficulty of patterning the barrier material 246 and/or the patterning the first WFM layer 244 at block 118 may be increased. For example, a stronger etch process may be performed to remove portions of the barrier material 246 and the first WFM layer 244 over the first region 1000. And the stronger etch process may induce damage to neighboring features formed near the barrier material 246 and the first WFM layer 244.

FIG. 23 depicts a diagram that illustrates a simulation result showing the relationship between the intensity of the silicon elements in the barrier layer 246′ and threshold voltage Vt of P-type transistor formed over the second region 2000. As described above and supported by this simulation result, the existence of the barrier layer 246′ contributes to a reduction in the threshold voltage of the P-type transistor. In addition, the higher the intensity of the silicon elements, the lower the threshold voltage of the P-type transistor.

Although not intended to be limiting, one or more embodiments of the present disclosure provide many benefits to a semiconductor device and the formation thereof. For example, the present disclosure provides a method of reducing aluminum diffusion in p-type gate structure without changing characteristics of n-type transistors by forming a barrier layer. The barrier layer may be a silicon layer formed by a soak process or an ALD process. By reducing aluminum diffusion, threshold voltages of p-type transistors may be advantageously lowered.

The present disclosure provides for many different embodiments. Semiconductor structures and methods of fabrication thereof are disclosed herein. In one exemplary aspect, the present disclosure is directed to a method. The method includes receiving a precursor structure comprising a first plurality of nanostructures over a first region, a second plurality of nanostructures over a second region, and, an isolation feature disposed between the first plurality of nanostructures and the second plurality of nanostructures, depositing a gate dielectric layer over the precursor structure, wherein a portion of the gate dielectric layer extends along a top surface of the isolation feature, forming a first work function metal layer over the second plurality of nanostructures over the second region without being formed over the first region, forming a barrier layer on the first work function metal layer, after the forming of the barrier layer, depositing a second work function metal layer over the precursor structure, the second work function metal layer comprising a first portion over the first region and a second portion over the second region, wherein a thickness of the second portion of the second work function metal layer is less than a thickness of the first portion of the second work function metal layer, and depositing a conductive layer over the second work function metal layer.

In some embodiments, the barrier layer may include silicon. In some embodiments, the first work function metal layer may include a p-type work function metal layer. In some embodiments, the second work function metal layer may include an n-type work function metal layer. In some embodiments, the forming of the first work function metal layer and the forming of the barrier layer on the first work function metal layer may include sequentially depositing a work function material layer and a barrier material layer over both the first region and the second region, forming a mask covering the second region, wherein the mask comprises an opening exposing a portion of the work function material layer over the first region, removing the portion of the work function material layer over the first region and a portion of the barrier material layer thereunder, thereby forming the first work function metal layer the barrier layer, respectively. In some embodiments, the first work function metal layer may include titanium nitride. In some embodiments, a total thickness of the barrier layer and the second portion of the second work function metal layer is less than the thickness of the first portion of the second work function metal layer. In some embodiments, the forming of the barrier layer may include performing an atomic layer deposition (ALD) process or a soak process. In some embodiments, a thickness of the barrier layer is between about 2 Å and about 10 Å.

In another exemplary aspect, the present disclosure is directed to a method. The method includes forming a channel region over a substrate, the channel region comprising a plurality of nanostructures, forming an isolation feature over the substrate and adjacent to a sidewall of the channel region, and forming a gate structure over the channel region and interfacing a top surface of the isolation feature, the forming of the gate structure comprises depositing a gate dielectric layer over the plurality of nanostructures and the isolation feature, depositing a p-type work function metal layer over the gate dielectric layer, soaking the p-type work function metal layer using a silicon-containing gas, after the soaking, depositing an n-type work function metal layer over the p-type work function metal layer and the isolation feature, wherein the n-type work function metal layer has a non-uniform thickness.

In some embodiments, the p-type work function metal layer may include titanium nitride, the n-type work function metal layer may include titanium aluminum nitride. In some embodiments, the silicon-containing gas may include silane or disilane. In some embodiments, the n-type work function metal layer may include a first portion over the p-type work function metal layer and a second portion over a portion of the isolation feature not overlapped with the p-type work function metal layer, and a thickness of the first portion of the n-type work function metal layer is less than a thickness of the second portion of n-type work function metal layer. In some embodiments, a thickness difference between the first portion of n-type work function metal layer and the second portion of the n-type work function metal layer is about 5 Å and about 15 Å. In some embodiments, the method may also include forming a protection layer over the n-type work function metal layer, wherein the protection layer comprises a titanium-containing layer. In some embodiments, the soaking forms a silicon layer on the p-type work function metal layer.

In yet another exemplary aspect, the present disclosure is directed to a semiconductor structure. The semiconductor structure includes a first base fin and a second base fin over a substrate, an isolation feature over the substrate and interfacing sidewalls of the first base fin and the second base fin, a first plurality of nanostructures disposed over the first base fin, a second plurality of nanostructures disposed over the second base fin, a gate dielectric layer wrapping around the first plurality of nanostructures and the second plurality of nanostructures, the gate dielectric layer being disposed over top surfaces of the first base fin, the second base fin, and the isolation feature, a first work function layer wrapping around the second plurality of nanostructures and disposed over the second base fin, a silicon-containing layer over the first work function layer, a second work function layer comprising a first portion wrapping around the first plurality of nanostructures over the first base fin and a second portion disposed over the silicon-containing layer, the first portion and the second portion having different thicknesses.

In some embodiments, the first work function layer may include a p-type work function material, and the second work function layer may include an aluminum-containing n-type work function material. In some embodiments, a thickness of the second portion of the second work function layer is less than a thickness of the first portion of the second work function layer. In some embodiments, the semiconductor device may also include one or more seams enclosed by the first work function layer.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, by implementing different thicknesses for the bit-line conductor and word line conductor, one can achieve different resistances for the conductors. However, other techniques to vary the resistances of the metal conductors may also be utilized as well.

What is claimed is:

1. A method, comprising:
receiving a precursor structure comprising:
a first plurality of nanostructures over a first region,
a second plurality of nanostructures over a second region, and,
an isolation feature disposed between the first plurality of nanostructures and the second plurality of nanostructures;
depositing a gate dielectric layer over the precursor structure, wherein a portion of the gate dielectric layer extends along a top surface of the isolation feature;
forming a first work function metal layer over the second plurality of nanostructures over the second region without being formed over the first region;
forming a barrier layer on the first work function metal layer;
after the forming of the barrier layer, depositing a second work function metal layer over the precursor structure, the second work function metal layer comprising a first portion over the first region and a second portion over the second region, wherein a thickness of the second portion of the second work function metal layer is less than a thickness of the first portion of the second work function metal layer; and
depositing a conductive layer over the second work function metal layer.

2. The method of claim 1, wherein the barrier layer comprises silicon.

3. The method of claim 1, wherein the first work function metal layer comprises a p-type work function metal layer.

4. The method of claim 1, wherein the second work function metal layer comprises an n-type work function metal layer.

5. The method of claim 1, wherein the forming of the first work function metal layer and the forming of the barrier layer on the first work function metal layer comprises:
sequentially depositing a work function material layer and a barrier material layer over both the first region and the second region;
forming a mask covering the second region, wherein the mask comprises an opening exposing a portion of the work function material layer over the first region;
removing the portion of the work function material layer over the first region and a portion of the barrier material layer thereunder, thereby forming the first work function metal layer the barrier layer, respectively.

6. The method of claim 1, wherein the first work function metal layer comprises titanium nitride.

7. The method of claim 1, wherein a total thickness of the barrier layer and the second portion of the second work function metal layer is less than the thickness of the first portion of the second work function metal layer.

8. The method of claim 1, wherein the forming of the barrier layer comprises performing an atomic layer deposition (ALD) process or a soak process.

9. The method of claim 1, wherein a thickness of the barrier layer is between about 2 Å and about 10 Å.

10. A method, comprising:
forming a channel region over a substrate, the channel region comprising a plurality of nanostructures;
forming an isolation feature over the substrate and adjacent to a sidewall of the channel region; and
forming a gate structure over the channel region and interfacing a top surface of the isolation feature, wherein the forming of the gate structure comprises:
depositing a gate dielectric layer over the plurality of nanostructures and the isolation feature,
depositing a p-type work function metal layer over the gate dielectric layer,
soaking the p-type work function metal layer using a silicon-containing gas,
after the soaking, depositing an n-type work function metal layer over the p-type work function metal layer and the isolation feature, wherein the n-type work function metal layer has a non-uniform thickness.

11. The method of claim 10,
wherein the p-type work function metal layer comprises titanium nitride,
wherein the n-type work function metal layer comprises titanium aluminum nitride.

12. The method of claim 10, wherein the silicon-containing gas comprises silane or disilane.

13. The method of claim 10, wherein the n-type work function metal layer comprises a first portion over the p-type work function metal layer and a second portion over a portion of the isolation feature not overlapped with the p-type work function metal layer, and a thickness of the first portion of the n-type work function metal layer is less than a thickness of the second portion of n-type work function metal layer.

14. The method of claim 13, wherein a thickness difference between the first portion of n-type work function metal layer and the second portion of the n-type work function metal layer is about 5 Å and about 15 Å.

15. The method of claim 10, further comprising:
forming a protection layer over the n-type work function metal layer, wherein the protection layer comprises a titanium-containing layer.

16. The method of claim 10, wherein the soaking forms a silicon layer on the p-type work function metal layer.

17. A semiconductor device, comprising:
a first base fin and a second base fin over a substrate;
an isolation feature over the substrate and interfacing sidewalls of the first base fin and the second base fin;
a first plurality of nanostructures disposed over the first base fin;
a second plurality of nanostructures disposed over the second base fin;
a gate dielectric layer wrapping around the first plurality of nanostructures and the second plurality of nanostructures, the gate dielectric layer being disposed over top surfaces of the first base fin, the second base fin, and the isolation feature;
a first work function layer wrapping around the second plurality of nanostructures and disposed over the second base fin;
a silicon-containing layer over the first work function layer;
a second work function layer comprising a first portion wrapping around the first plurality of nanostructures over the first base fin and a second portion disposed over the silicon-containing layer, the first portion and the second portion having different thicknesses.

18. The semiconductor device of claim 17, wherein the first work function layer comprises a p-type work function material, and the second work function layer comprises an aluminum-containing n-type work function material.

19. The semiconductor device of claim 17, wherein a thickness of the second portion of the second work function layer is less than a thickness of the first portion of the second work function layer.

20. The semiconductor device of claim 17, further comprising:
one or more seams enclosed by the first work function layer.
